(19) United States
(12) Patent Application Publication
(10) Pub. No.: US 2003/0008503 A1
(43) Pub. Date: Jan. 9, 2003

(54) Chamber conditioning method

(75) Inventors: Shin-Yi Tsai, Hsin-Chu (TW); Ming-Chung Liang, Taipei (TW); Chun-Hung Lee, Tao-Yuan (TW); Shiuh-Sheng Yu, Chi-Lung (TW)

Correspondence Address: Benjamin J. Hauptman, LOWE HAUPTMAN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 09/895,387

(22) Filed: Jul. 2, 2001

(51) Int. Cl. H01L 21/302

(52) U.S. Cl. 438/689

(57) ABSTRACT

This invention provides a method for chamber conditioning with deposition mode. The method includes performing organic gas introduced constantly into a chamber, wherein said organic gas comprises halogen. Adhesive polymers are formed from said organic gas and particles in the chamber, and deposited onto the wall of the chamber to form heavy polymers subsequently. It is necessary to make a similar chamber condition for manufacturing every batch of wafer. In other words, the development of a non-ignored pollution problem, which is increasing with batches of the manufacturing of wafers will not occur. By using said method of deposition mode, it is speedily and easy to decrease the amount of particles in the chamber for the requirement for wafer manufacturing.

### BACKGROUND OF THE INVENTION

1. Field of the Invention

The proposed invention is related to a chamber conditioning method and more particularly to a method for applying “deposition mode” to down the amount of particles in that chamber to an acceptable range.

2. Description of the Prior Art

The requirements of semiconductor manufacturing must be performed under an extremely clean environment. Products of the reactions in said manufacturing are not only deposited onto wafers as desired, but also attached to the wall of the manufacturing chamber. During manufacturing, the pollutant, such as particles, will be deposited and accumulated gradually onto the wall and components of the chamber. Over time, if the particles fail to be cleaned from the chamber, a degraded, unreliable processes and defective substrates may result. Lack of a regular procedure for cleaning causes the migration of the particle residues onto substrates and pollution of said manufacturing process. Particularly, when the residues are peeling, the yield kill rate can be higher than 10%. Thus, it is necessarily to look for an efficient and economical chamber conditioning method to lower the amount of particles in the chamber so as to enhance the property and quality of the products from the chamber. Traditionally, there are two methods of chamber conditioning, i.e. in-situ cleaning (also known as dry cleaning) and wet cleaning.

In opposition to the dry cleaning procedure, in which the processing chamber remains closed, the wet cleaning procedure is performed by breaking the processing chamber's vacuum seal and manually wiping down the chamber's interior surfaces. Such a wet cleaning operation affects a processing system's throughput in a worse way than a dry cleaning operation does. When a wet clean is performed, opening the processing chamber and physically wiping the chamber's interior surfaces results in more down-time (about 14 to 16 hours), compared to the dry clean which only takes minutes, because the process must subsequently be re-stabilized. A wet clean procedure is normally performed to remove residues that are not entirely removed by the in-situ cleaning process, and thus slowly accumulate over time. After longer periods of time, typically about 9000 RF-minutes (150 RF-hour), a wet clean is required to be performed.

The above-mentioned process of chamber conditioning of the clean mode at least comprises the following, shown as the flow chart as FIG. 1:

Firstly, at least one gas, such as SF₆, Cl₂, O₂ and the like, is introduced into a chamber, which contains particles. Particles in the chamber will react with said gas and become a volatile gas, shown as the forming volatile gas step 10. Then the gas in the chamber is pumped away with vacuum system, shown as the pumping step 12, and process gas is purged into the chamber to displace the gas in the chamber, shown as the gas displacement step 14. Finally, as shown in the test step 16, a test wafer is used to confirm whether the influence of the particle residues in the chamber on process of wafer manufacturing is qualified as desired or not. If the answer is “no”, it is necessary to return to the forming volatile gas step 10, and repeat the conditioning steps.

Wherein said chamber conditioning method with dry cleaning procedure, particles in the chamber are taken away by reacting with the introduced gas to form volatile gas, and pumping away with a vacuum system. There are some particles probably still remaining in the chamber after the pumping step. It is because the introduced gas can not completely react with particles in the chamber.

Wherein said chamber conditioning method with a dry cleaning procedure, the above-mentioned method usually takes a long time because of the complexity of the chamber, and thus it will affect the throughput of the manufacturing. Furthermore the particle residues, which are still attached to wall of the chamber after chamber conditioning, may escape from the wall, become a pollutant source in the subsequent manufacture, and affect the stability of the manufacturing.

Wherein said chamber conditioning method with dry cleaning procedure, it is necessary to perform a judging step using test wafers to confirm the influence of the particle residues on the manufacture. Said step is not only inconvenient, but also very uneconomical for wafer manufacturing.

In said traditional chamber conditioning method with clean mode, clean gas is introduced into a chamber 20, shown as FIG. 2A. Under power from an upper electrode 24 and a lower electrode 26, particles in said chamber 20 react with the introduced gas and form volatile products 28, as shown in FIG. 2B. Sequentially, volatile gas 28 and inactive clean gas are pumped out from chamber 20 shown in FIG. 2C. Refer to FIG. 2D, a test wafer 32 is sent into the chamber 20 and used to confirm the influence of particle residues 30 on the manufacturing. For example, in Shallow Trench Isolation etching process, the chamber conditioning process is completed, when depth of the trenches on test wafers reach to the desired level of stability. On the other hand, the chamber conditioning process has to be repeated if the depth of the trench can not reach to the desired stable level.

Downtime of performing the clean mode process means the damage of throughput of wafer. Thus, it is very important to lower downtime of chamber conditioning to rise the throughput of wafer. For this object, in other words, it is necessary to broaden the meantime between clean process, wherein said clean process is wet clean procedure which consumes much time. So it is important to find out some kind of method to improve the chamber conditioning method. Especially, it is necessary to provide a method for lowering the influence of particles in the manufacture and rising the yield and throughput of wafer.

### SUMMARY OF THE INVENTION

In accordance with the present invention, a method is provided for chamber conditioning that is useful for stabilizing of the wafer manufacture.

It is another object of this invention to simplify the process of chamber conditioning and to make the control of the process of chamber conditioning more easily.

It is a further object of this invention to increase stability of the subsequent process of manufacture.

It is still another object of this invention that it is not necessary to use a test wafer in chamber conditioning process.

It is yet another object of this invention that it is not necessary to pass through the steps of pumping and purging and the introducing gases that will not cause influence in subsequent manufacturing process.

In accordance with the above-mentioned objects, the presented invention provides a new chamber conditioning method, in which introduced organic gas comprising halide is utilized to form adhesive polymer with particles. The polymer will deposit on wall of the chamber and form heavy polymers. Preferably, said organic gas will not influence manufacturing semiconductor. Thus it will lower the amount of particles in the chamber speedily, and make the controlling of the process of chamber conditioning more easily.

On the other hand, the polymers formed from particles and the introduced gas can fasten particles on the wall of the chamber; thus there is no particle escaping from the wall and becoming a source of influence in manufacturing. Preferably, the adhesive heavy polymers, which are formed from the deposition of the adhesive polymer, can stabilize manufacture by trapping particles produced in the manufacturing.

In one preferred embodiment, the presented invention provides a chamber conditioning process with deposition mode. The process comprises the following steps. Firstly, at least one organic gas is introduced into a chamber. Secondly, adhesive polymers are formed from the introduced gas and particles in the chamber. Then the polymers are deposited to wall of the chamber and formed heavy polymers. Finally, the chamber conditioning is completed when the heavy polymer is saturated.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is an essential flow diagram showing the steps of traditional of chamber conditioning process with clean mode.

FIG. 2A to FIG. 2C are a series of qualitative illustrations of traditional chamber conditioning process with clean mode.

FIG. 3 is an essential flow diagram showing the steps of this presented invention of chamber conditioning process with deposition mode.

FIG. 4A to FIG. 4C are a series of qualitative illustrations of this presented invention of chamber conditioning process with deposition mode.

FIG. 5 is an illustration showing the application of the presented invention in a chamber of Shallow Trench Isolation Etching process.

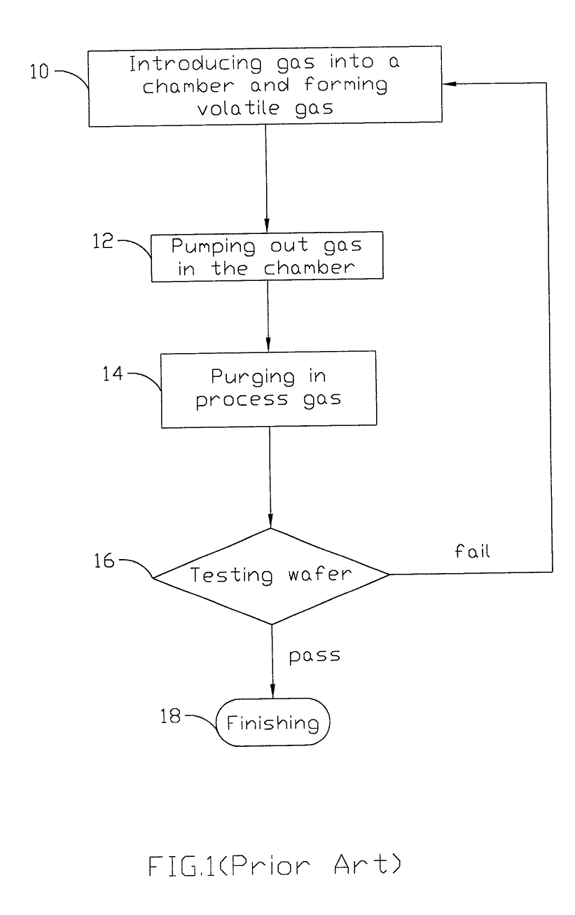

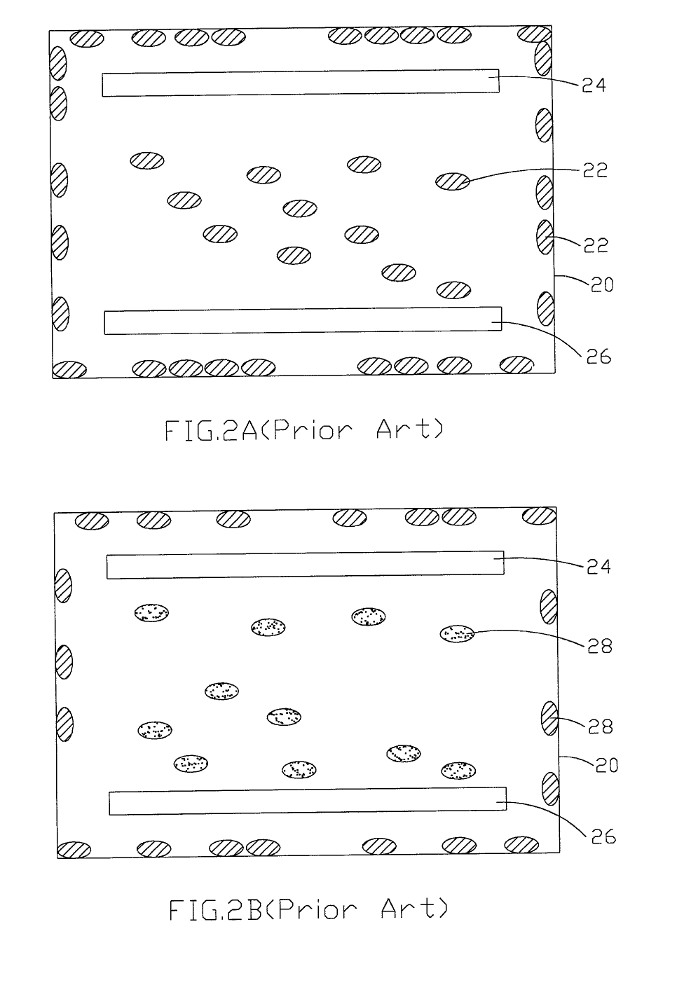

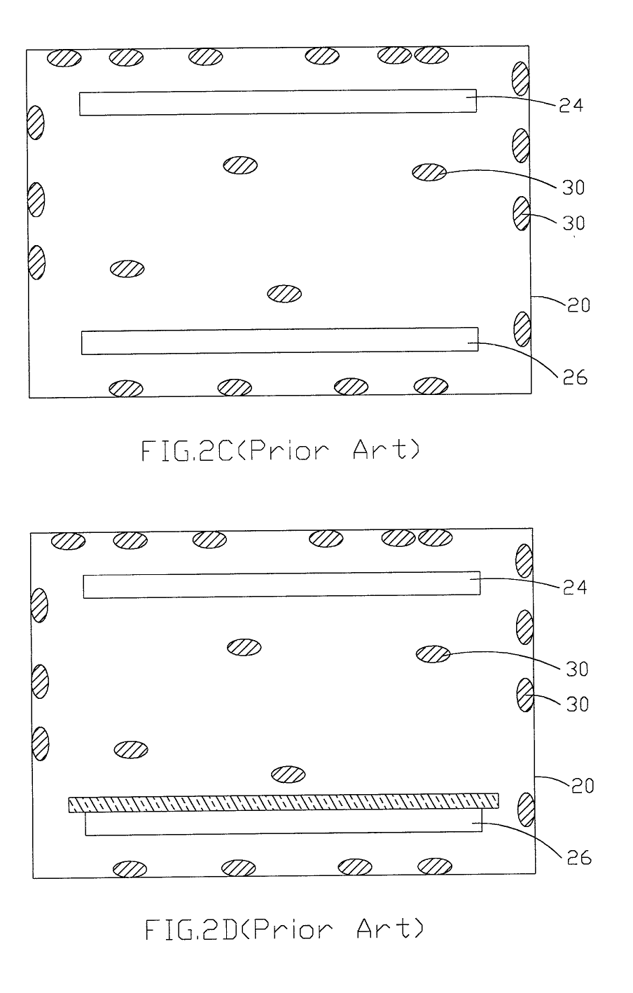

### DESCRIPTION OF THE PREFERRED EMBODIMENTS

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

It is important to control the amount of particles in a chamber in a suitable range during wafer manufacturing. The point of the presented invention is providing a chamber conditioning process with deposition mode. Wherein above-mentioned process, organic gas is constantly introduced into a chamber and thus adhesive polymers are formed from particles in the chamber and the introduced gas. Said polymers are deposited onto the wall of the chamber and formed heavy polymers until said heavy polymers are saturated. The above-mentioned process can speedily lower the amount of particles in the chamber to a desired level and make the controlling of chamber conditioning process more efficient and easy.

This presented invention provides a chamber conditioning process with deposition mode. The above-mentioned process can transfer particles in the chamber into polymers and fix the polymers onto walls of the chamber while wafer manufacturing is performed. Thus the process does not have to expend minutes for chamber conditioning before every wafer manufacturing.

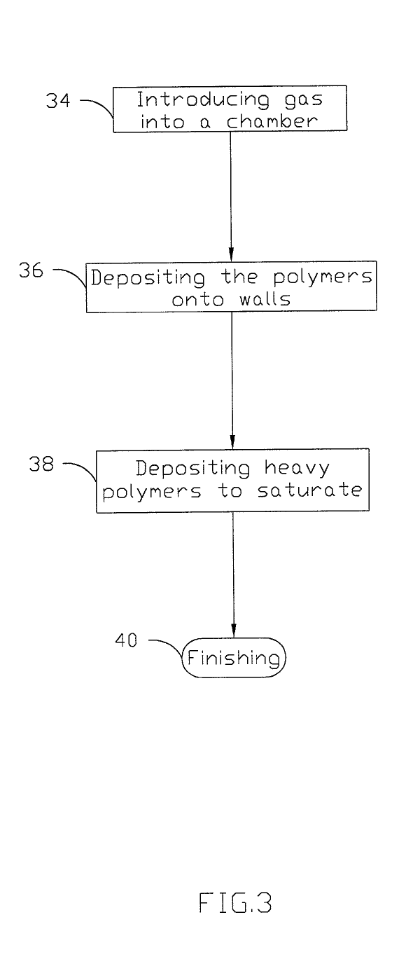

All of the chamber conditioning process can be shown as a flow diagram as FIG. 3. Firstly, at least one organic gas comprising halogen is introduced into a chamber, wherein the organic gas substantially comprises elements of carbon, hydrogen, oxygen, and halogen. In this embodiment, the preferred gas is CH₂CF₂, or CHF₃. The introduced gas forms adhesive polymers with particles in the chamber, shown as step 34 for forming polymer. The polymers are deposited onto the wall of the chamber, and heavy polymers are formed, shown as step 36 for depositing polymer. Refer to step 38 for judging the clean level, when the deposition of the polymer is saturated, i.e. when the etching rate of the wafer in the chamber is stable, it means chamber conditioning of the chamber is finished, shown as step 40 for finishing chamber conditioning.

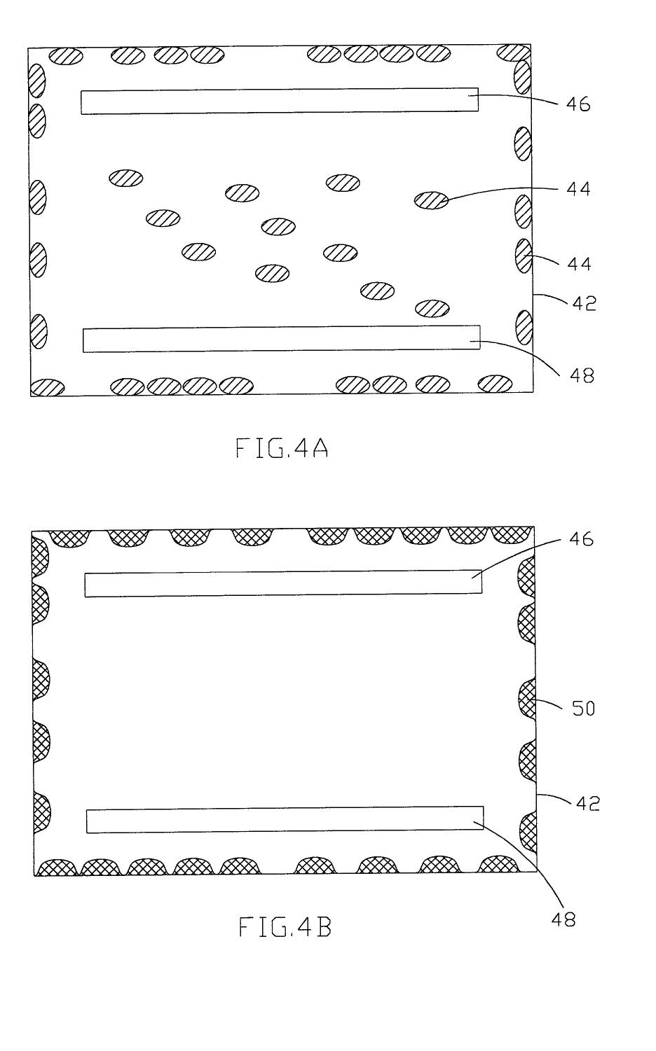

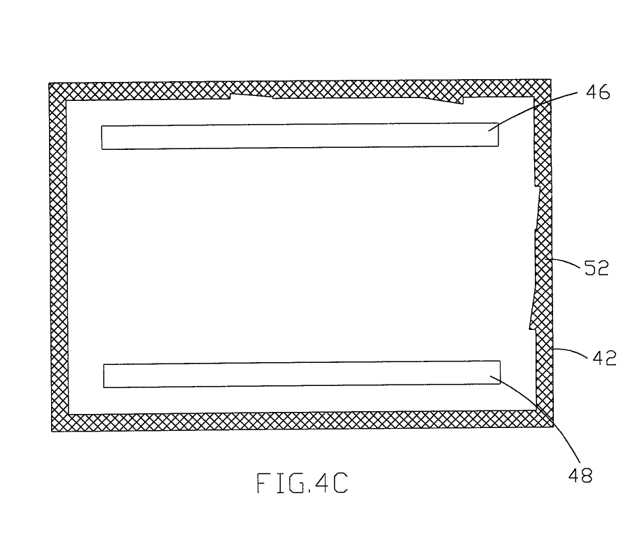

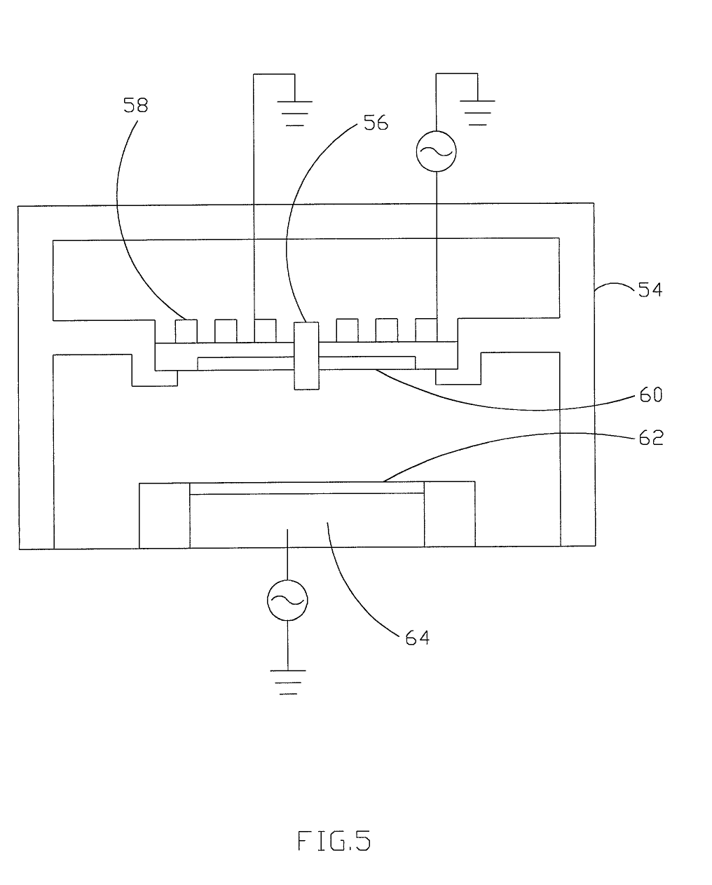

One preferred embodiment of this presented invention is a chamber conditioning process with deposition mode. A preferred embodiment according to this invention is set forth below and referred to FIG. 4.

After used to produce several batches of wafers, there are particles 44 that will affect the yield of next manufacturing existing in a chamber 42, as shown in FIG. 4A.

At least one organic gas containing halogen is constantly introduced into the chamber 42, wherein the organic gas substantially comprises elements of carbon, hydrogen, oxygen, and halogen. In this embodiment, the preferred gas is CH₂CF₂, or CHF₃. Under power from an upper electrode 46 and a lower electrode 48, particles 44 in the chamber 42 are reacted with the introduced gas and formed adhesive polymers 50, shown as FIG. 4B. Through above-mentioned step, the organic gas is helpful not only for fixing particles, but also for trapping the suspended particles and fixing them onto wall of the chamber 42. Thus the step can decrease the influence of particle for efficiency of wafer manufacturing.

Referred to FIG. 4C, the polymers 50 adhered onto wall of chamber 42 are deposited and formed heavy polymers 52. When the deposition of the heavy polymers 52 are saturated, chamber conditioning process is finished, and the next manufacture can be begun. The deposited heavy polymer on the wall of the chamber will be cleaned by wet clean when the device is in periodical clean.

Because of the organic gas constantly introduced into the chamber, the polymers formed from the particles are deposited onto wall until the deposition of the polymers is saturated, and thus the process can decrease the amount of suspended particles and keep the stability of the later manufacturing.

One of the differences between the deposition mode and clean mode is necessary of using a test wafer. In the deposition mode, the chamber conditioning is finished when the deposition of the polymer on the wall is saturated. It is not necessary to use a test wafer to ensure the influence of the particle residues in the chamber. The chamber can be an etching chamber, which can be applied to Sallow Trench Isolation etching.

About the comparison between the above-mentioned two chamber conditioning methods, the chamber conditioning with clean mode and the chamber conditioning with deposition mode, it is shown in Table 1 behind this article. In regards to compare the cost time of chamber conditioning, in deposition mode, the particles become polymers and attach onto the wall. So, it does not have to perform the steps of pumping out the particles, as clean mode, before the next manufacture. In other words, deposition mode can save time in pumping and switching the valve of the chamber during this step, so it can finish chamber conditioning in a shorter time.

Moreover, in chamber conditioning method with deposition mode, if sad organic gas is constantly introduced into the chamber, there are polymers formed and deposited onto the wall of the chamber to form heavy polymers until the deposition of the heavy polymers is saturated. Thus the above-mentioned method makes the operation of chamber conditioning easier and controllable. Because the particles (polymers) are deposited onto the wall directly, the efficiency of chamber conditioning is not limited to the complexity of the chamber's inner structure.

The adhesive polymers formed from particles and the introduced gas can fix the particles onto the wall of the chamber, so it will not allow that particles to escape from wall and affect the stability of wafer manufacturing. Moreover, the adhesive heavy polymers deposited on wall of the chamber may trap some of particles produced during manufacturing, and help to keep the stability of the subsequent manufacturing.

In order to describe the presented invention concretely, another preferred embodiment shown in FIG. 5 is a stable method of Shallow Trench Isolation etching (STI etching), wherein the method comprising the following steps:

The process gas is introduced from a gas inlet 56, through a shower head 60, into a Shallow Trench Isolation etching chamber 54. The process gas comprises etching gas and organic gas, which comprises elements of carbon, hydrogen, oxygen, and halogen. In this preferred embodiment, the more preferable gas is CH₂F₂, or CHF₃.

After respectively electrifying a coil 58 and a substrate 64, the introduced gas is formed plasma in chamber 54, and begun to work. The introduced etching gas will etch wafer 62, and the introduced organic gas will form adhesive polymers with particles in chamber 54. The two kinds of reaction can be carried out at the same time, and they will not influence each other.

The adhesive polymers are deposited onto wall of the chamber 54, and formed heavy polymers. The saturation of deposition of the heavy polymers is shown as the stability of the etching rate in the manufacturing. When the etching rate tends to be stable, most of the particles are transferred to polymers and deposited onto wall of chamber 54.

In the above-mentioned embodiment, the chamber has to be wet clean every 3000 wafers to certify the quality of wafers from the chamber.

In the preferred embodiment, it is not required to stop the manufacturing and carry out the chamber conditioning process after each ending of wafer manufacturing. It is only necessary to control the mix ratio of process gas and the organic gas in the introduced gas to perform manufacturing and particle trapping at the same time.

Although specific embodiments have been illustrated and described, it will be obvious to those skilled in the art that various modifications may be made without departing from what is intended to be limited solely by the appended claims.

TABLE 1
Comparison between deposition mode and clean mode

| Clean mode | Deposition mode |
|---|---|
| Performing after each ending of | passable performing during the |
| manufacture | manufacture |
| Introducing etching gas | introducing mix gas |
| Pumping out particles (volatile gas) | depositing particles (polymer) |
| | onto wall of the chamber |
| Limiting the efficiency to the | Not limiting the efficiency to the |
| structure of chamber | structure of chamber |
| Controlling not easy | Controlling easy. |
| Test wafer necessary | Test wafer not necessary |

What is claimed is:

1. A chamber conditioning method in manufacturing semiconductor, said method comprising:
introducing an organic gas comprising halogen into a chamber, wherein said organic gas forms adhesive polymers with particles; and
depositing the polymers onto wall of the chamber.

2. The method according to claim 1, wherein said chamber is an etching chamber.

3. The method according to claim 1, wherein said organic gas comprises oxygen atom.

4. The method according to claim 1, wherein said organic gas is selected from the group consisting of CH₃F, CH₂F₂, and CHF₃.

5. The method according to claim 1, further comprising a step for judging clean level of the chamber.

6. The method according to claim 5, wherein said judging step is to use a test wafer to check whether etching rate of the test wafer in the chamber is stable.

7. The method according to claim 6, wherein said chamber conditioning is completed when said etching rate is stable.

8. A chamber conditioning method for etching chamber, wherein said method comprising:
introducing an organic gas comprising halogen into a chamber, wherein said organic gas forms adhesive polymers with particles in the etching chamber; and
depositing the polymers onto wall of the chamber.

9. The method according to claim 8, wherein said organic gas comprises oxygen atom.

10. The method according to claim 8, wherein said organic gas is selected from the group consisting of CH₃F, CH₂F₂, and CHF₃.

11. The method according to claim 8, further comprising a step for judging clean level of the chamber.

12. The method according to claim 11, wherein said judging step is to use a test wafer to check whether etching rate of the test wafer in the chamber is stable.

13. The method according to claim 12, wherein said chamber conditioning is completed when said etching rate is stable.

14. A chamber conditioning method in manufacturing semiconductor, wherein said method comprising:
introducing an organic gas comprising halogen into a chamber;
utilizing said organic gas to adhere particles in the chamber and forming adhesive polymers;
depositing the polymers onto wall of the chamber; and
judging clean level of the chamber.

15. The method according to claim 14, wherein said chamber is an etching chamber.

16. The method according to claim 14, wherein said organic gas comprises oxygen atom.

17. The method according to claim 14, wherein said organic gas is selected from the group consisting of CH₃F, CH₂F₂, and CHF₃.

18. The method according to claim 14, wherein said judging step is to use a test wafer to check whether etching rate of the test wafer in the chamber is stable.

19. The method according to claim 14, wherein said chamber conditioning is completed when said etching rate is stable.
